(19) United States
(12) Patent Application Publication
(10) Pub. No.: US 2008/0232419 A1
(43) Pub. Date: Sep. 25, 2008

(54) Laser array chip, laser module, manufacturing method for manufacturing laser module, manufacturing method for manufacturing laser light source, laser light source, illumination device, monitor, and projector

(75) Inventors: Akira Egawa, Shiojiri-shi (JP); Kunihiko Takagi, Okaya-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/076,498

(22) Filed: Mar. 19, 2008

(30) Foreign Application Priority Data
Mar. 22, 2007 (JP) 2007-074115
Mar. 23, 2007 (JP) 2007-076111

(51) Int. Cl. H01S 5/10; H01L 33/00; H01L 21/02

(52) U.S. Cl. 372/50.12; 438/34; 257/E33.001; 257/E21.002

(57) ABSTRACT

A laser array chip includes: a plurality of emission sections emitting laser lights; and a weak section formed in a portion in the thickness direction of at least a portion of the areas between the emission sections, whose strength is weaker than the strength of areas in which the emission sections are formed.

### CROSS-REFERENCE TO RELATED APPLICATION

This application is based on and claims priority from Japanese Patent Application No. 2007-074115, filed on Mar. 22, 2007, and Japanese Patent Application No. 2007-076111, filed on Mar. 23, 2007, the contents of which are incorporated herein by reference.

### BACKGROUND

1. Technical Field

The present invention relates to a laser array chip, a laser module, a manufacturing method for manufacturing a laser module, a manufacturing method for manufacturing a laser light source, a laser light source, an illumination device, a monitor, and a projector.

2. Related Art

Conventionally, semiconductor laser elements are GaAs system edge-emission type semiconductor laser elements formed on GaAs substrate.

Such semiconductor laser elements are not limited to a single emission section. In order to realize a laser having high level of output power, there are constitutions in which a laser array, in which a plurality of emission sections which emit laser lights are formed, is configured on a single laser element.

A laser element on which a plurality of emission sections are formed in this way is connected to a submount using solder or another method.

In particular, in the case of a semiconductor laser element having a plurality of emission sections, in order to reinforce the mechanical strength, the semiconductor laser element is connected onto the submount.

As the submount, a multilayer substrate, which is an aluminum nitride substrate with extremely high thermal conductivity and excellent thermal dissipation, is used.

However, when after connecting the laser element and the submount via the solder, and when the temperature of the laser element and submount is returned to normal temperature, stresses occur within the laser element due to the difference in thermal expansion coefficients of the two members, and so there is the problem in that the service lifetime of the laser element is shortened.

Furthermore, warping of the laser element and submount occurs, and so there is the problem in that scattering occurs in the position of the beam emitted by the laser.

In Japanese Unexamined Patent Application, First Publication No. 2002-299744, a semiconductor assembly is proposed in that the semiconductor laser element is connected with the submount.

In the semiconductor assembly described in this reference, because the difference between the thermal expansion coefficients of the semiconductor laser element and the submount results in the occurrence of thermal stress in the semiconductor laser element, in order to avoid damage, the thickness of the submount is increased. Furthermore, a method is disclosed in which, by determining the combination of materials used in the laser element, submount, and heat sink as well as the thickness of the submount, stress within the laser element is suppressed.

Furthermore, in Japanese Unexamined Patent Application, First Publication No. 2005-19804, an apparatus is disclosed in which numerous laser elements are each connected to a submount and arranged in an array.

However, in the semiconductor assembly described in the above Japanese Unexamined Patent Application, First Publication No. 2002-299744, the submount thickness is increased to relax the stress applied to the semiconductor laser element, but the thicker the submount is made, the greater is the thermal resistance.

When a material having a linear expansion coefficient close to the linear expansion coefficient of the laser element is used in the submount, the range of materials which can be used is severely limited.

For example, when the laser element is formed from GaAs (gallium arsenide), because the linear expansion coefficient of GaAs is 5.9×10⁻⁶ (1/K), often AIN (aluminum nitride), with a linear expansion coefficient of 4.5×10⁻⁶(1/K), is used in the submount.

However, AIN has the problems of high cost, and heat dissipation is degraded, due to the fact that the thermal conductivity is approximately 200 W/mK.

As a result, there is the problem in that heat generated by the semiconductor laser element is not easily dissipated.

Furthermore, indium solder is used when connecting a semiconductor laser element to a submount, but there are the problems in that indium (In) solder is easily oxidized, easily diffuses, and is expensive.

Furthermore, when using the method described in the above Japanese Unexamined Patent Application, First Publication No. 2002-299744, which determines the combination of materials used in the laser element, submount, and heat sink, as well as the thickness of the submount, the respective materials which can be used are limited to a narrow range, and moreover the thickness of the submount is also limited.

Hence a method is conceivable in which, in place of indium solder, the semiconductor laser element is connected to the submount via gold-tin (Au—Sn) solder.

However, gold-tin, while having satisfactory electrical and thermal conductivity as well as chemical stability, is a hard material. Consequently, when packaging a semiconductor laser element on a submount, there is the problem in that stresses between the semiconductor laser element and the submount cannot be absorbed by the gold-tin solder. As a result, there are concerns that the semiconductor laser element may be damaged.

Furthermore, in an apparatus in which numerous laser elements are each connected to submounts, such as described in the above Japanese Unexamined Patent Application, First Publication No. 2005-19804, there is the problem in that scattering in positional precision occurs when arranging the laser elements into an array.

### SUMMARY

An advantage of some aspects of the invention is to provide a laser array chip, a laser module, a manufacturing method for manufacturing a laser module, a manufacturing method for manufacturing a laser light source, a laser light source, an illumination device, a monitor, and a projector, in which reliability is improved by suppressing the stress within a laser element occurring when the laser element is connected to a submount and returns to normal temperature and warping of the laser element and submount, in which the materials which can be used in the laser element and submount are not limited to a narrow range, and in which laser elements can be arranged in an array with a high level of positional precision.

A first aspect of the invention provides a laser array chip including: a plurality of emission sections emitting laser lights; and a weak section formed in a portion in the thickness direction of at least a portion of the areas between the emission sections, whose strength is weaker than the strength of areas in which the emission sections are formed.

A laser array chip of the invention is advantageous when the linear expansion coefficient of the substrate (submount) on which the laser array chip is packaged is lower than the linear expansion coefficient of the laser array chip.

Generally, the linear expansion coefficients of a laser array chip and of the submount on which the laser array chip is packaged are different.

As a result, when the laser array chip is packaged on the submount, stress occurring in the laser array chip causes strain to occur, and there is concern that the laser array chip may be damaged.

However, in the invention, a weak section is formed in a portion in the thickness direction of the laser array chip in a portion of the areas between emission sections, having low strength compared with the portions in which the emission sections are formed, and so stress applied to the laser array chip is concentrated in the weak section.

As a result, when stress is applied to the laser array chip, the weak section cracks easily, so that damage to the emission sections of the laser array chip can be avoided, and a laser array chip with a high level of reliability can be provided.

It is preferable that, in the laser array chip of the first aspect of the invention, the weak section be a portion in which the thickness of the laser array chip is decreased due to a groove formed in the thickness direction of the laser array chip.

In the laser array chip of the invention, the weak section is a portion whose thickness is reduced by forming a groove in the thickness direction, so that the laser array chip can crack without affecting emission sections.

Hence a laser array chip with a high level of reliability can be manufactured.

It is preferable that the laser array chip of the first aspect of the invention further include a plurality of weak sections. In the laser array chip, the strengths of the weak sections are different from each other depending on the positions on which the weak sections are formed.

In the laser array chip of the invention, the weak sections in areas between emission sections at which the stress applied to the laser array chip is high are made high in strength among the plurality of weak sections. Also, the weak sections in areas between emission sections at which the stress applied to the laser array chip is low are made low in strength among the plurality of weak sections.

By forming weak sections according to the stresses applied to the laser array chip in this way, the stresses applied to the weak sections between all of the emission sections become substantially uniform.

Hence a large load is not imparted to places where great stresses are applied to the laser array chip, and so even in cases where there is cracking of the laser array chip, damage to emission sections can be avoided.

A second aspect of the invention provides a laser module including: a laser element having a plurality of emission sections emitting laser lights, and a rupture section caused by a weak section formed in a portion in the thickness direction of at least a portion of the areas between the emission sections, the strength of the weak section being weaker than the strength of areas in which the emission sections are formed; and a supporting substrate having a linear expansion coefficient lower than the linear expansion coefficient of the laser element, and on which the laser element is packaged.

For example, if the laser element is used for a long period of time, a large amount of heat is generated by the laser element, and there are cases in which stress occurs in the laser element.

If no countermeasures are taken to deal with this problem, stresses may cause damage to the laser element.

The laser module of the invention has a rupture section caused by a weak section.

In this constitution, damage to emission sections of the laser element can be avoided, so that a laser module with a high level of reliability can be provided.

Furthermore, in manufacturing processes when packaging a laser array chip on a submount, a rupture section caused by a weak section can be formed.

It is preferable that, in the laser module of the second aspect of the invention, the weak section be a portion in which the thickness of the laser element is decreased due to a groove formed in the thickness direction of the laser element.

In the laser module of the invention, by forming the groove in the thickness direction, the weak section is in a portion whose thickness is reduced, so that the laser element can crack without affecting emission sections.

Hence a laser module with a high level of reliability can be manufactured.

Even when a laser element is cracked at each emission section, such portions are called grooves.

It is preferable that, in the laser module of the second aspect of the invention, the laser element have a package face on which the supporting substrate is packaged, and the groove be formed on the package face.

In the laser module of the invention, when packaging, a groove is formed in the package face of the laser array chip in contact with the supporting substrate, so that tensile stress in the laser element is concentrated in the weak section.

In this constitution, the laser element, in which a weak section is formed, cracks readily in the thickness direction.

Hence when stress is applied to the laser element, the weak section is caused to crack intentionally, so that damage to the emission sections can be avoided.

It is preferable that, in the laser module of the second aspect of the invention, the laser element and the supporting substrate be connected via a connecting material including hard solder material.

In general, when a material containing a hard solder is used as a connecting material, even when stress occurs between the laser element and the supporting substrate, the connecting material cannot absorb this stress.

However, in the case of a laser module of the invention, the linear expansion coefficient of the supporting substrate is lower than the linear expansion coefficient of the laser element, and a weak section is formed in the laser element, so that tensile stress applied to the laser element is concentrated at the weak section.

Hence even if the connecting material contains hard solder, the laser element can be firmly packaged on the supporting substrate without causing damage to emission sections of the laser element.

A third aspect of the invention provides a manufacturing method for manufacturing a laser module, the manufacturing method including: providing a laser array chip having a plurality of emission sections emitting laser lights; forming a weak section, in a portion of the thickness direction of the laser array chip, in at least a portion of the areas between the emission sections of the laser array chip; connecting the laser array chip to a supporting substrate using a connecting material that has been heated; and packaging the laser array chip on the supporting substrate.

In the manufacturing method of the invention, at first, a weak section is formed in a portion of the laser array chip in the thickness direction and in at least a portion of the areas between emission sections in the face of the laser array chip packaged on the supporting substrate.

Thereafter, using the connecting material that has been heated, the laser array chip and the supporting substrate are connected.

Then, as the connecting material cools, stress occurs in the laser array chip due to the difference between the linear expansion coefficient of the laser array chip and the linear expansion coefficient of the supporting substrate.

At this time, because the linear expansion coefficient of the supporting substrate is lower than the linear expansion coefficient of the laser array chip, stress applied to the laser array chip is concentrated in the weak section.

Hence due to contraction of the laser array chip, stress is concentrated in the weak section of the laser array chip, and so cracking occurs readily in the thickness direction of the laser array chip in which the weak section has been formed.

In this manufacturing method, when stress is applied to the laser array chip, the weak section tends to crack, so that damage to the emission section can be avoided.

That is, a laser module with a high level of reliability can be manufactured.

It is preferable that, in the manufacturing method of the third aspect of the invention, the laser array chip have a package face on which the supporting substrate is packaged, the weak section be formed on the package face of the laser array chip, and the weak section be a portion in which the thickness of the laser array chip is reduced due to a groove formed in the thickness direction of the laser array chip.

In the manufacturing method of the invention, a groove is formed in the package face of the laser array chip to be packaged on the supporting substrate.

In this constitution, by forming the groove in the thickness direction of the laser array chip, a portion whose thickness is reduced is the weak section.

Hence even when the linear expansion coefficient of the supporting substrate is lower than the linear expansion coefficient of the laser array chip, the laser array chip easily cracks due to the weak section without affecting emission sections, so that a laser module with a high level of reliability can be manufactured.

A fourth aspect of the invention provides a projector including: a light source device having the above-described laser module; and an image formation device utilizing light emitted from the light source device and causing images having a desired size to be displayed on a display screen.

In the projector of the invention, light emitted from the light source device is incident into the image formation device. An image having a desired size is displayed on the display screen by the image formation device.

At this time, as described above, the projector includes a light source device having a highly reliable laser module, so that the reliability of the projector itself can also be improved.

A fifth aspect of the invention provides a laser array chip including: a plurality of emission sections including a first emission section and a second emission section adjacent to the first emission section; and at least two division initiation sections, in the area between the first emission section and the second emission section, along the direction of arrangement of the emission sections.

In the laser array chip of the invention, at least two division initiation sections are provided between the adjacent first emission section and second emission section, along the direction of arrangement of the emission sections.

In this constitution, the laser array chip can be divided into a plurality of laser elements based on these division initiation sections, and moreover unnecessary portions surrounded by the division initiation sections can be removed.

It is preferable that the laser array chip of the fifth aspect of the invention further include a first face and a second face on the side opposite the first face. In the laser array chip, the division initiation sections are formed on each of the first face and the second face, and the intervals between the division initiation sections formed on the first face are narrower than the intervals between the division initiation sections formed on the second face.

In the laser array chip of the invention, when the laser array chip is divided into a plurality of laser elements, unnecessary portions surrounded by division initiation sections can easily be removed.

It is preferable that, in the laser array chip of the fifth aspect of the invention, the division initiation sections be groove portions formed on the first face and the second face.

According to the laser array chip of the invention, it is possible to reliably divide into a plurality of laser elements from the groove portions which are division initiation sections.

It is preferable that, in the laser array chip of the fifth aspect of the invention, the division initiation sections be modification sections formed in the laser array chip.

According to the laser array chip of the invention, it is possible to reliably divide into a plurality of laser elements from the modification sections which are division initiation sections.

A sixth aspect of the invention provides a manufacturing method for manufacturing a laser light source, the manufacturing method including: providing a laser array chip having a plurality of emission sections including a first emission section and a second emission section adjacent to the first emission section; forming, on the laser array chip, at least two division initiation sections at which the laser array chip is initially divided so as to divide the laser array chip into a plurality of laser elements, between the first emission section and the second emission section, along the direction of arrangement of the emission sections; connecting the laser array chip in which the division initiation sections are formed, to a submount; and dividing the laser array chip which has been connected to the submount into the laser elements.

In the manufacturing method of the invention, after forming at least two division initiation sections in the area between the adjacent first emission section and second emission section of the laser array chip, the laser array chip is connected to the submount.

Then, the laser chip, in a state of being connected to the submount, is divided into a plurality of laser elements based on the division initiation sections. In this manufacturing method, a laser array chip can be divided into a plurality of laser elements based on the division initiation sections. Furthermore, unnecessary portions surrounded by division initiation sections can be removed.

Also, the a laser array is constituted by the laser elements that have been divided, and the length in the array direction of the divided laser elements can be shortened.

In this constitution, the occurrence of stress within the laser elements, occurring due to the difference between linear expansion coefficients of the laser array chip and submount, can be suppressed, and the lifetime of the laser elements can be extended, and reliability improved.

Furthermore, the occurrence of warping of the laser array chip and of the submount can be suppressed.

As a result, the laser array with a high level of positional precision can be obtained, and shifting of emitted laser light and degradation of the positional precision of the laser light source can be prevented.

It is preferable that, in the manufacturing method of the sixth aspect of the invention, in the dividing of the laser array chip, cracks be occurred at the division initiation sections at which the laser array chip is initially divided so as to divide the laser array chip into the laser elements, due to the stress caused by the difference in the linear expansion coefficients of the laser array chip and the submount.

In the manufacturing method of the invention, since the laser array chip is automatically divided by the stress caused by the difference in the linear expansion coefficients of the laser array chip and the submount, so that the task of dividing the laser array chip into a plurality of laser elements can be simplified.

It is preferable that, in the manufacturing method of the sixth aspect of the invention, the laser array chip have a first face facing to the submount when the laser array chip is connected to the submount and a second face which is opposite side of the first face. In the manufacturing method, in the forming of the division initiation sections, the division initiation sections are formed in the laser array chip so that the intervals between the division initiation sections in the first face are narrower than the intervals in the second face.

According to the manufacturing method of the invention, when a laser array chip is divided into a plurality of laser elements, unnecessary portions surrounded by the division initiation sections can easily be removed.

It is preferable that, in the manufacturing method of the sixth aspect of the invention, the division initiation sections be groove portions formed in the first face and the second face.

By the manufacturing method of the invention, the laser array chip can be reliably divided from the groove portions serving as division initiation sections.

It is preferable that, in the manufacturing method of the sixth aspect of the invention, the division initiation sections be modification sections formed in the laser array chip.

By the manufacturing method of the invention, the laser array chip can be reliably divided from the modification sections serving as division initiation sections.

It is preferable that, in the manufacturing method of the sixth aspect of the invention, the laser array chip be constituted by a material including a GaAs, and the submount be constituted by a material including a copper.

In the manufacturing method of the invention, by using a material containing copper in the submount, costs can be reduced, and moreover high thermal conductivity can be obtained, compared with the AIN generally used in submounts.

A seventh aspect of the invention provides a laser light source manufactured by the above-described manufacturing method.

In the laser light source of the invention, by suppressing the occurrence of stress within laser elements, suppressing the occurrence of warping in the plurality of laser elements and in the submount, and securing high positional precision of the laser array, shifting of the emitted laser light and degradation of positional precision can be prevented.

An eighth aspect of the invention provides a laser light source device including the laser light source described above, and an external resonance mirror causing the light emitted from the laser light source to be resonated.

In the laser light source device of the invention, when using an external resonance mirror, it is possible to efficiently oscillate the laser light emitted from the laser light source with a high level of positional precision and emit the laser light having high level of output power with a high level of reliability.

A ninth aspect of the invention provides an illumination device including the above-described laser light source.

By an illumination device of the invention, a laser light source emits the laser light having high level of output power with a high level of reliability, so that it is possible to efficiently and stably irradiate illumination light with a high level of performance.

A tenth aspect of the invention provides a monitor including: the above-described laser light source; and an image capturing section which captures images of objects irradiated by the laser light source.

By a monitor of the invention, the laser light having high level of output power is emitted from the laser light source with a high level of reliability, so that the brightness of captured images obtained by the image capturing section can be stably increased.

An eleventh aspect of the invention provides a projector including: the above-described laser light source; and an image formation device utilizing light from the laser light source and causing images having a desired size to be displayed on a display screen.

By the projector of the invention, the laser light having high level of output power is emitted from the laser light source with a high level of reliability, so that high-brightness images can be stably displayed.

### BRIEF DESCRIPTION OF THE DRAWINGS

FIG. 1 is a perspective view showing the laser module of a first embodiment of the invention.

FIGS. 2A and 2B are views showing the laser array chip of the invention, FIG. 2A is a cross-sectional view showing the laser array chip, and FIG. 2B is an enlarged cross-sectional view showing the area indicated by reference numeral U in FIG. 2A.

FIG. 3 is a cross-sectional view showing a process of packaging the laser array chip of the first embodiment of the invention on a supporting substrate.

FIG. 4 is a cross-sectional view showing a process of packaging the laser array chip of the first embodiment of the invention on a supporting substrate.

FIGS. 5A and 5B are views showing a process of packaging the laser array chip of the first embodiment of the invention on a supporting substrate, FIG. 5A is a cross-sectional view, and FIG. 5B is an enlarged cross-sectional view showing the area indicated by reference numeral V in FIG. 5A.

FIG. 6 is a cross-sectional view showing a process of packaging the laser array chip of the first embodiment of the invention on a supporting substrate.

FIG. 7 is a cross-sectional view showing a portion of the laser module of the first embodiment of the invention.

FIG. 8 is a plane view showing a modified example of the laser array chip of the first embodiment of the invention.

FIG. 9 is a cross-sectional view showing a modified example of a laser array chip used in the laser module of the first embodiment of the invention.

FIG. 10 is a schematic view showing a configuration of a projector of a second embodiment of the invention.

FIG. 11 is a schematic plan view showing a laser light source of a third embodiment of the invention, and is viewed from the top of the laser light source in the vertical direction (Z direction).

FIG. 12 is a side view showing the laser light source of the third embodiment of the invention, and is viewed from the side of the laser light source (X direction).

FIGS. 13A and 13B are views showing the laser light source of the third embodiment of the invention, FIG. 13A is a side view showing the configuration of the laser light source viewed from a side (Y direction), and FIG. 13B is an enlarged cross-sectional view showing the area indicated by reference numeral R in FIG. 13A.

FIGS. 14A and 14B are schematic views illustrating processes to manufacture the laser light source of the third embodiment of the invention, FIG. 14A is a plane view seen from the Z direction, and FIG. 14B is a side view seen from the Y direction.

FIGS. 15A to 15C are schematic views illustrating processes to manufacture the laser light source of the third embodiment of the invention, FIG. 15A is a plane view seen from the Z direction, FIG. 15B is a side view seen from the Y direction, and FIG. 15C is an enlarged cross-sectional view showing the area indicated by reference numeral S in FIG. 15B.

FIGS. 16A and 16B are schematic views illustrating processes to manufacture the laser light source of the third embodiment of the invention, FIG. 16A is a plane view seen from the Z direction, and FIG. 16B is a side view seen from the Y direction.

FIGS. 17A to 17C are schematic views illustrating processes to manufacture the laser light source of the third embodiment of the invention, FIG. 17A is a plane view seen from the Z direction, FIG. 17B is a side view seen from the Y direction, and FIG. 17C is an enlarged cross-sectional view showing the area indicated by reference numeral Tin FIG. 17B.

FIGS. 18A to 18C are schematic views illustrating processes to manufacture the laser light source of a fourth embodiment, FIG. 18A is a plane view seen from the Z direction, FIG. 18B is a side view seen from the Y direction, and FIG. 18C is an enlarged cross-sectional view showing the area indicated by reference numeral W in FIG. 18B.

FIG. 19 is a schematic view of the configuration of the illumination device of a fifth embodiment.

FIG. 20 is a schematic view of the configuration of the monitor of a sixth embodiment.

FIG. 21 is a schematic view of the configuration of the image display device of a seventh embodiment.

### DESCRIPTION OF EXEMPLARY EMBODIMENTS

Hereinafter, embodiments of a laser array chip, a laser module, a manufacturing method for manufacturing a laser module, a manufacturing method for manufacturing a laser light source, a laser light source, an illumination device, a monitor, and a projector of the invention are explained, referring to the drawings.

In the following drawings, the scale of various members is changed as appropriate in order to display members at a size enabling recognition.

### First Embodiment

A manufacturing method for manufacturing a laser module of this embodiment is explained.

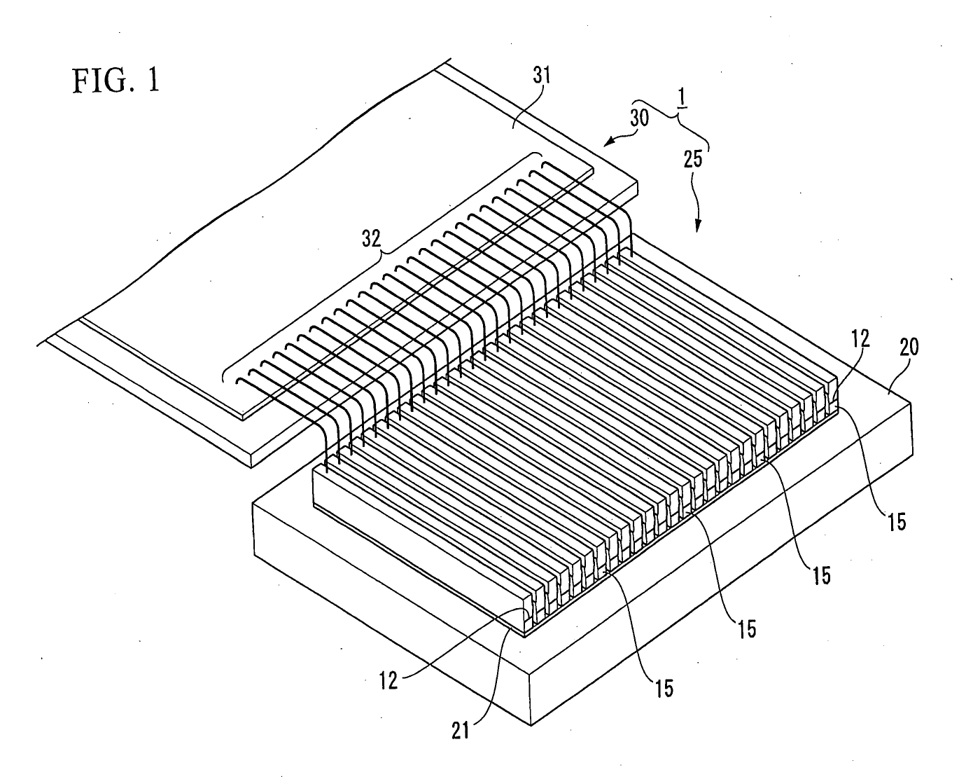

First, the configuration of the laser module manufactured using the manufacturing method for manufacturing a laser module of this embodiment is explained referring to FIG. 1

As shown in FIG. 1, the laser module 1 includes a laser light source 25 and a current-supplying substrate 30.

The laser light source 25 includes a plurality of laser elements 15, a submount 20 (supporting substrate), and a current-supplying substrate 30.

The submount 20 supports the plurality of laser elements 15, and provides reinforcement to enhance mechanical strength.

As explained below, the plurality of laser elements 15 are obtained by dividing the laser array chip 10 packaged on the submount 20 into a plurality of laser elements 15.

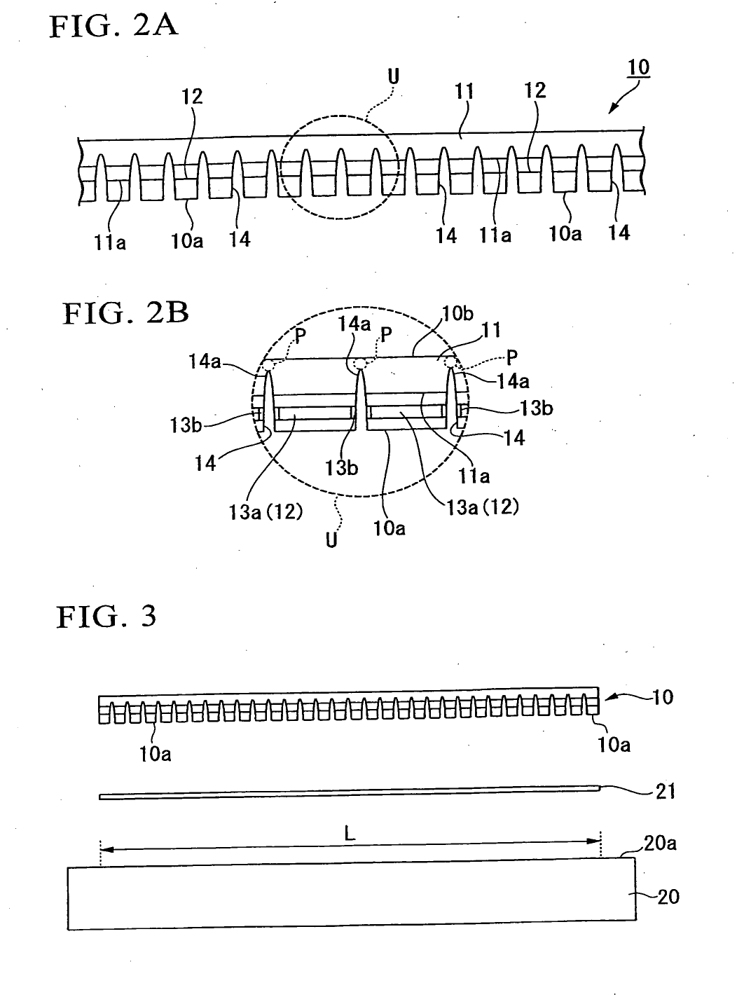

First, the laser array chip 10 packaged on the submount 20 is explained referring to FIGS. 2A and 2B.

FIGS. 2A and 2B show a laser array chip of the invention. FIG. 2A cross-sectionally shows the laser array chip. FIG. 2B cross-sectionally shows in enlargement the area indicated by reference numeral U in FIG. 2A.

As shown in FIG. 2A, the laser array chip 10 is an edge-emission type semiconductor laser, in which a plurality of emitters 12 (emission sections) which emit laser light are arranged in one-dimensional direction.

Specifically, as shown in FIG. 2B, in the laser array chip 10, a plurality of layers, including active layers 13a having a quantum-well structure, are layered on one face 11a of a semiconductor substrate 11.

These active layers 13a are emitters 12 which emit laser light.

Moreover, insulating layers 13b are formed on both sides of the active layers 13a. The active layers 13a and insulating layers 13b are formed in alternation in the longitudinal direction of the laser array chip 10.

Also, the face on which the terminating layer is exposed among the plurality of layers formed on the semiconductor substrate 11 is the package face 10a, and the laser array chip 10 is packaged on the submount 20 at this package face 10a.

Furthermore, grooves 14 are formed in the thickness direction of the laser array chip 10 from the package face 10a of the laser array chip 10, in areas containing the insulating layer 13b.

The areas P between the end portions 14a of the grooves 14 in the thickness direction of the laser array chip 10 and the end face 10b opposite the package face 10a (portions which are made thin) are weak sections.

That is, grooves 14 are formed between the emitters 12.

The grooves 14 can be formed by, for example, photolithography and etching techniques.

It is preferable that the depth of these grooves 14 be the depth from the package face 10a until the semiconductor substrate 11 is reached, and that the grooves be formed at least sufficiently deep to divide the emission sections.

The depths of the grooves 14 between the emitters 12 are substantially equal.

The laser array chip 10 is constituted by a semiconductor material including gallium (Ga) and arsenic (As).

The linear expansion coefficient of this laser array chip 10 is approximately 6×10⁻⁶/K.

The submount 20 is constituted by a diamond, with a linear expansion coefficient of approximately 1×10⁻⁶/K.

As shown in FIG. 1, the current-supplying substrate 30 is a flexible substrate on which a wiring patter 31 is formed. The wiring patter 31 supplys current to the laser array chip 10.

Electrodes (not shown) are provided for each emitter 12 on the upper face and lower face of the laser element 15.

Bonding wires 32 are bonded to the wiring pattern 31 from the electrodes on the upper face of the laser array chip 10.

Next, FIGS. 3 to 7 are referenced to explain a manufacturing method for manufacturing a laser module 1 in which the laser array chip 10 of this embodiment, configured as described above is packaged on a submount 20. FIGS. 3, 4, 6, and 7 are cross-sectional views showing processes to package the laser array chip 10 on the submount 20. FIGS. 5A and 5B show a process of packaging the laser array chip 10 of the invention on the submount 20. FIG. 5A is a cross-sectional view. FIG. 5B is an enlarged cross-sectional view showing the area indicated by reference numeral V in FIG. 5A.

First, as shown in FIG. 3, in the process of packaging the laser array chip 10 on the submount 20, the laser array chip 10, die-attach film 21, and submount 20 are prepared. In FIG. 3, the area L of the upper face 20a of the submount 20 is the area on which the laser array chip 10 is packaged. The die-attach film 21 is formed from an Au—Sn (gold-tin) alloy material (connecting material). The melting point of the die-attach film 21 of Au—Sn (gold-tin) used in this embodiment is 287° C.

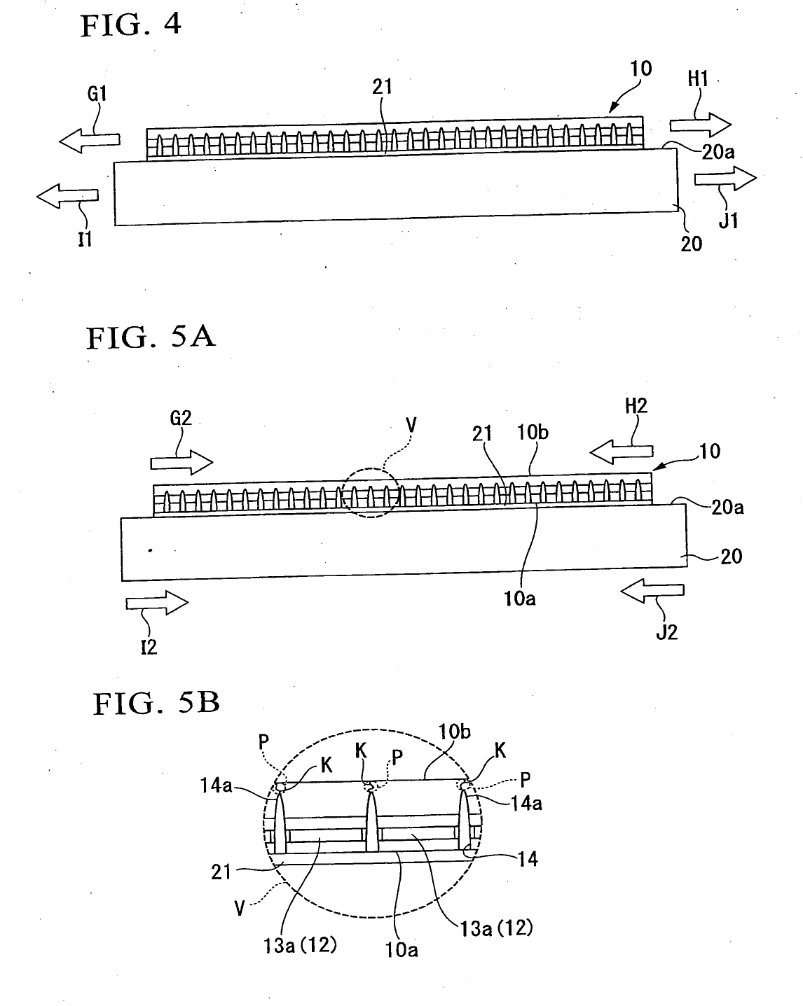

Next, as shown in FIG. 4, the laser array chip 10 is placed on the upper face 20a of the submount 20, with the die-attach film 21 intervening, in the area L of the upper face 20a of the submount 20. Then, when the submount 20 is heated to approximately 300° C., the die-attach film 21 is melted, and the laser array chip 10 expands toward the outside of the submount 20 as indicated by the arrows G1 and H1, and the submount 20 also expands outward as indicated by the arrows I1 and J1.

Thereafter, the temperature of the submount 20 on which the laser array chip 10 is packaged is naturally cooled to normal temperature, and the laser allay chip 10 is fixed on the submount 20.

In this manner, in the cooling the submount 20 and the laser array chip 10, as indicated in FIG. 5A, due to the difference in linear expansion coefficients of the laser array chip 10 and the submount 20, the contraction amounts are different, and so stress occurs in the laser array chip 10.

That is, the linear expansion coefficient of the laser array chip 10 is greater than the linear expansion coefficient of the submount 20, so that compared with the contracting force toward the center of the submount 20 (arrows I2 and J2 in FIG. 5A), the contracting force toward the center of the laser array chip 10 (arrows G2 and H2 in FIG. 5A) is greater.

Hence a tensile stress occurs in the laser array chip 10, and a compressive stress occurs in the submount 20.

At this time, as shown in FIG. 5B, due to the stress concentrated in the center portion of the laser array chip 10, tensile stress occurs in the laser array chip 10.

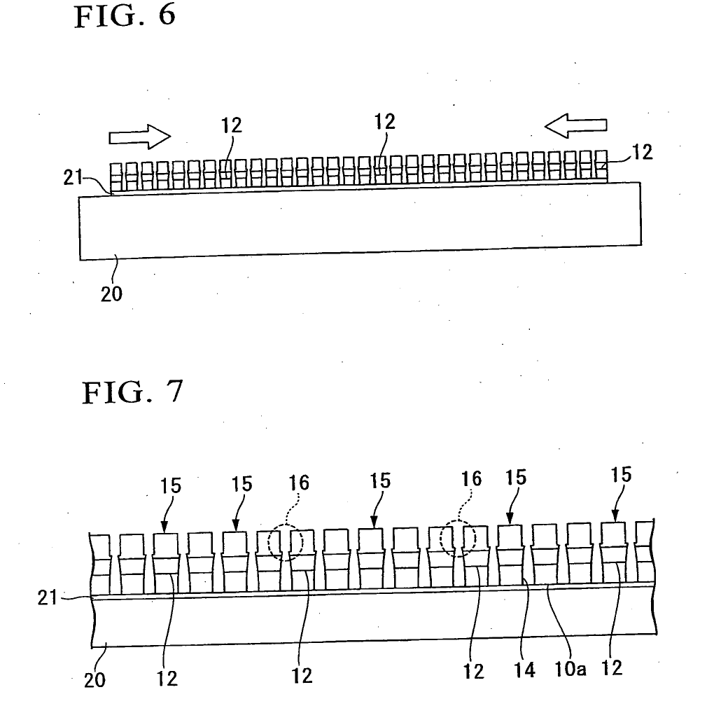

That is, through concentration of stress in the areas P (weak areas) of the laser array chip 10, cracks K occur from the edge portions 14a of the grooves 14 in the laser array chip 10 to the end face 10b. In this manner, as shown in FIG. 6, the laser array chip 10 is divided into emitters 12 so that the emitters 12 are separated.

In this manner, as shown in FIG. 7, the laser elements 15 each having one emitter 12 are formed. Also, rupture sections 16 caused by the areas P (weak sections) are formed between the laser elements 15.

In the example shown in FIG. 7, a state is shown in which the laser array chip 10 is entirely divided into individual emitters 12. However, depending on the manner of application of stress to the laser array chip 10, there may be cases in which some emitters 12 are not divided.

As shown in FIG. 1, the bonding wires 32 are then bonded from each of the laser elements 15 to the wiring pattern 31.

Each of the laser elements 15 is electrically connected by at least one bonding wire 32 to the wiring pattern 31.

In this manner, current is supplied to each of the laser elements 15 from the current-supplying substrate 30.

In the manufacturing method for manufacturing the laser module of this embodiment, grooves 14 are formed in the laser array chip 10 in the thickness direction of the laser array chip 10 (emitters 12). Also, the laser array chip 10 is packaged on a submount 20 having the linear expansion coefficient lower than the linear expansion coefficient of the laser array chip 10.

In this manner, stress applied to the laser array chip 10 is concentrated in the areas P which are weak sections formed by grooves 14, so that cracking easily occurs in these areas P.

Therefore, damage to the emitters 12 of the laser array chip 10 can be avoided.

Thus, a laser module 1 having a high level of reliability can be provided.

Moreover, by forming grooves 14 in the package face 10a of the laser array chip 10, stress tends to concentrate in the areas P.

As a result, cracks K readily form in the areas P in the thickness direction of the laser array chip 10 in which grooves 14 are formed.

By this manufacturing method, stress applied to the laser array chip 10 can be relaxed without affecting the emitters 12, and a laser module can be manufactured with a high level of reliability.

In general, when using connecting material including Au—Sn (material used in hard solder) as the connecting material to connect a laser array chip 10 and submount 20, even when stress occurs between the laser array chip 10 and submount 20, this stress cannot be absorbed by the connecting material including Au—Sn.

In contrast, in the manufacturing method of the invention for manufacturing the laser array chip, the linear expansion coefficient of the submount 20 is lower than the linear expansion coefficient of the laser array chip 10, and grooves 14 are formed in the laser array chip 10, so that stress applied to the laser array chip 10 is concentrated in the areas P.

Hence even when the connecting material is a material formed from Au—Sn, the laser array chip 10 can be firmly fixed on the submount 20 without causing damage to the emitters 12 of the laser array chip 10.

In this embodiment, the grooves 14 are formed in all of the areas between emitters 12. But it is sufficient to form a groove 14 in at least one area between emitters 12.

Furthermore, grooves 14 are formed from the package face 10a of the laser array chip 10. But grooves may be formed from the end face 10b toward the package face 10a.

Furthermore, grooves 14 are formed in order to form weak sections, but other methods may be used.

That is, a method may be used in which the apparent shape is not changed, for example, by performing partial modification or other processing in the thickness direction, to form portions which are weaker than other portions.

Also, laser light or the like may be used to form portions which are weaker than other portions in the intermediate portions from the package face 10a toward the end face 10b.

Also, an edge-emission type semiconductor laser is used as the laser array chip 10. But even when using a surface-emission laser, by forming weak sections between the emission sections, similar advantageous results can be obtained.

When using a surface-emission laser, the laser array chip 10 is not limited to a laser array chip 10 in which the plurality of emitters 12 are arranged in one dimension, but may be a laser array chip 35 having emission sections 35a arranged in a two-dimensional arrangement.

In this laser array chip 35, by forming grooves 36 in a lattice shape between the emission sections 35a, a plurality of laser elements in a two-dimensional shape can be obtained.

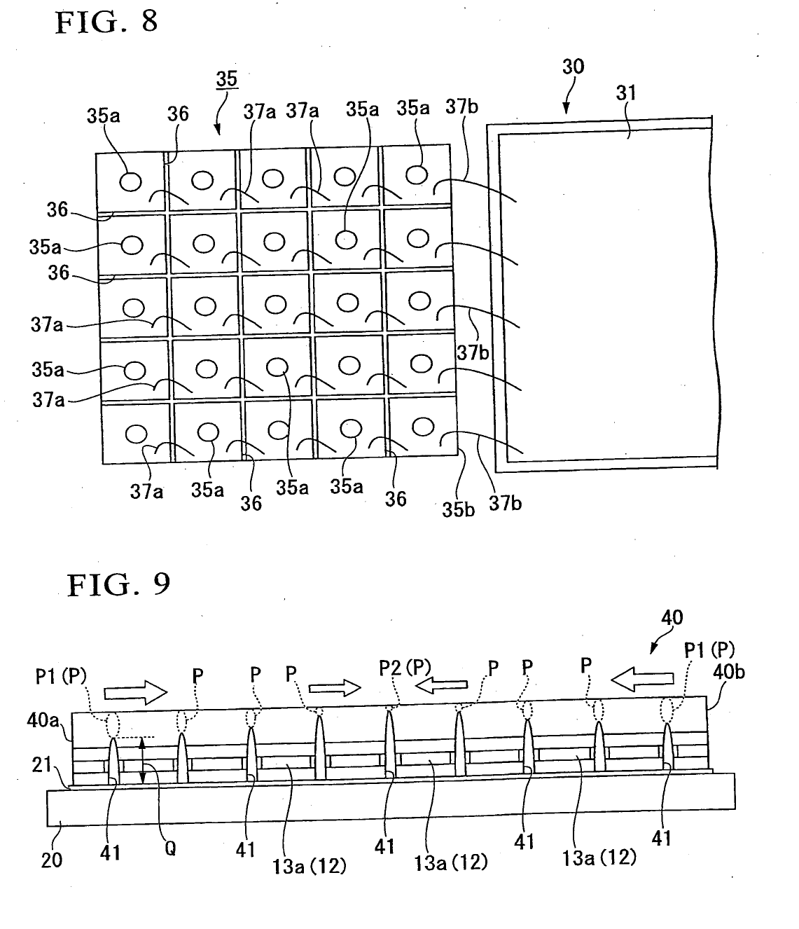

In this case, as shown in FIG. 8, adjacent laser elements are electrically connected using bonding wires 37a, and bonding wires 37b are formed from the laser elements of the end face 35b to the wiring pattern 31 of the current-supplying substrate 30.

One bonding wire may also be provided from each laser element having a single emitter to the wiring pattern 31 of the current-supplying substrate 30.

Furthermore, it is desirable that the submount 20 be placed on a heat sink formed from material having a high level of thermal conductivity, such as for example copper (Cu).

In this constitution, heat generated by laser elements 15 can be transmitted from the submount 20 to the heat sink and dissipated.

Here, if the laser elements 15 are used for a long period of time, the temperature of the laser elements 15 rises, and metal used in wiring and electrodes moves over insulating material (migration phenomenon), so that there are cases in which defects occur due to degradation of the insulating resistance between electrodes.

However, by placing the submount 20 on a heat sink having a high level of thermal conductivity, heat from the laser elements 15 can be more effectively dissipated, so that occurrence of the above-described defects can be prevented.

Furthermore, in this embodiment, the heated submount was caused to cool naturally. But forcible cooling using a cooling device or similar may be performed.

Furthermore, as the hard solder material, Au—Sn was used, but other materials may be used.

### Modified Example of the First Embodiment

In the first embodiment shown in FIG. 2, the depths of the grooves 14 between emitters 12 are substantially equal, but a laser array chip 40 in which the depths of grooves 41 between emitters 12 are different depending on the position at which the groove 41 is formed may be packaged on a submount 20.

Such a modified example is explains referring to FIG. 9.

In this modified example, when packaging the laser array chip 40 on the submount 20, the stress applied to the end faces 40a and 40b is greater than the stress applied to the center portion of the laser array chip 40.

Hence as shown in FIG. 9, the grooves 41 are formed so that the depth Q is greater in moving from the end faces 40a and 40b toward the center portion.

In this constitution, among the areas P which are weak sections formed by the grooves 41 in the laser array chip 40, compared with the strength of areas P1 which are weak sections formed by grooves 41 on the sides of the end faces 40a and 40b of the laser array chip 40, the strength of the area P2 which is the weak section formed by a groove 41 in the center portion is weaker.

That is, the areas P1 between emitters 12 formed at positions close to the end faces 40a and 40b, where the stress applied to the laser array chip 40 is greater, are made stronger among the plurality of grooves 41, and the area P2 between emitters 12 formed at a position near the center, where the stress applied to the laser array chip 40 is lower, is made weaker among the plurality of grooves 41.

Using such a laser array chip 40, packaging on the submount 20 is performed similarly to the first embodiment.

In the manufacturing method for manufacturing the laser module of this modified example, by determining the depth of the grooves 41 depending on the stress applied to the laser array chip 40, the tendency toward cracking in the areas P1 and P2 between all the emitters 12 during cooling can be made substantially uniform.

Hence the load applied to portions where the stress applied to the laser array chip 40 is great is not excessive, so that division can be performed with less of an effect on the emitters 12 of the laser array chip 40.

Moreover, the depths of the grooves 41 need not be made deeper in moving toward the center portion, and adjustments may be made as appropriate depending on the shape of the submount 20 for packaging and other parameters.

That is, the depths of the grooves 41 need not be determined so as to change by a fixed amount, for example, the depths of the grooves 41 may be partially increased so that the strength of weak sections between emitters 12 for which easier cracking is desired is reduced, depending on the state of the submount 20 for packaging.

### Second Embodiment

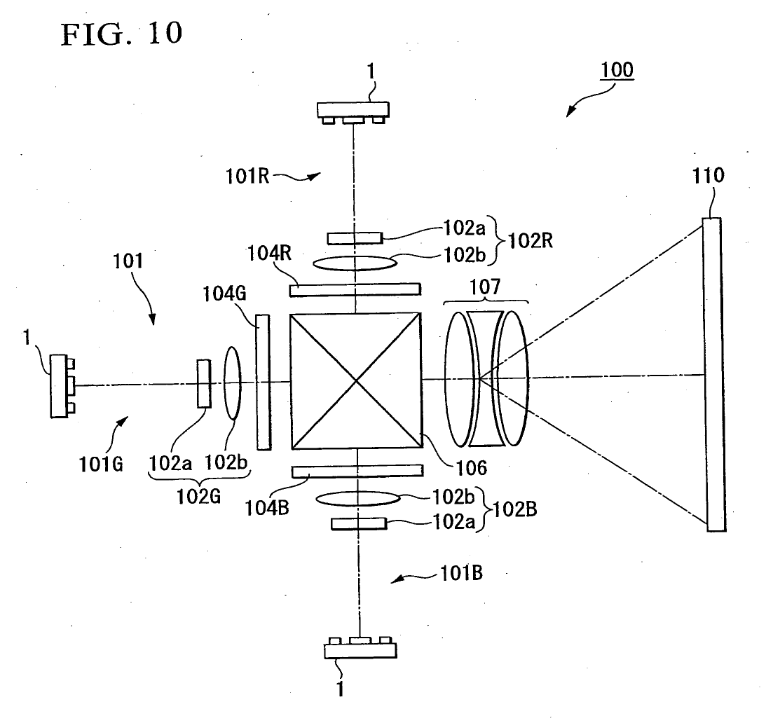

Next, a second embodiment of the invention is explained, referring to FIG. 10.

For purposes of simplification, in FIG. 10, a housing of the projector 100 is not shown.

In the projector 100, a red laser light source device 101R (light source device), a green laser light source device 101G (light source device), and a blue light source device 101B (light source device), which emit red light, green light, and blue light, respectively, are light source devices 101 having laser modules 1 of the above first embodiment.

The projector 100 includes an image formation device, having liquid crystal light valves 104R, 104G, and 104B (light modulation devices), which modulate the laser light emitted from the laser light source devices 101R, 101G, and 101B, respectively, and a projection lens 107 (projection device), which enlarges and projects images formed by the liquid crystal light valves 104R, 104G, and 104B onto a screen (display screen) 110.

Furthermore, the projector 100 includes a cross-dichroic prism 106 (colored light synthesizing section), which synthesizes the light emitted from the liquid crystal light valves 104R, 104G, and 104B, and guides the light to the projection lens 107.

Furthermore, the projector 100 includes uniformizing optical systems 102R, 102G, and 102B, on the downstream side of the optical path from the laser light source devices 101R, 101G, and 101B, in order to uniformize the illumination distribution of laser light emitted from the laser light source devices 101R, 101G, and 101B. The liquid crystal light valves 104R, 104G, and 104B are illuminated with the light having the illumination distribution which has been uniformized by these optical systems.

For example, the uniformizing optical systems 102R, 102G, and 102B may be configured using a hologram 102a and field lens 102b.

Light of three colors modulated by the liquid crystal light valves 104R, 104G, and 104B is incident into the cross-dichroic prism 106.

This prism is formed by laminating four right-angle prisms. Also, this prism includes a dielectric multilayer film which reflects red light and a dielectric multilayer film which reflects blue light, on the inner faces of the prism in a cross shape.

The light beams of three colors are synthesized by these dielectric multilayer films, forming light which expresses a color image.

The synthesized light is then projected onto the screen 110 by the projection lens 107, which is a projection optical system, and an enlarged image is displayed.

In the above-described projector 100 of this embodiment, the red laser light source device 101R, the green laser light source device 101G, and the blue laser light source device 101B have the laser module 1 having a high level of reliability. Therefore, the reliability of the projector 100 itself can also be improved.

The projector of this embodiment was explained as using the laser module 1 of the first embodiment in the red, green, and blue laser light source devices 101R, 101G, and 101B. However, modules in which laser array chips 40 were explained in the modified example of the first embodiment can also be used.

At this time, light source devices having different laser modules can be used as the respective light source devices 101, or light source devices with the same laser modules can be used.

Furthermore, in the above explanation, transmissive liquid crystal light valves were used as light modulation devices, but light valves other than liquid crystal light valves may be used, or reflective light valves may be used.

As the light valves, for example, reflective liquid crystal light valves, and digital micromrirror devices, may be used.

The configuration of the projection optical system can be modified depending on the type of light valve used as needed.

Furthermore, the laser module of the first embodiment (including the modified example) can also be applied to the light source devices of scanning-type image display devices (projectors), having scanning section which is an image formation device which, by scanning laser light from a laser light source device (light source device) onto a screen, displays an image of desired size on the display screen.

The technical scope of the invention is not limited to the above embodiments, and various modifications can be made without deviating from the gist of the invention.

For example, in the above second embodiment, a cross-dichroic prism was used as the colored light synthesizing section, but other constitutions may be used.

As the colored light synthesizing section, dichroic prisms arranged in a cross configuration to synthesize colored light, or dichroic mirrors arranged in parallel to synthesize colored light, can also be used.

### Third Embodiment

### Laser Light Source

First, the configuration of the laser light source of a third embodiment to which the invention is applied is explained.

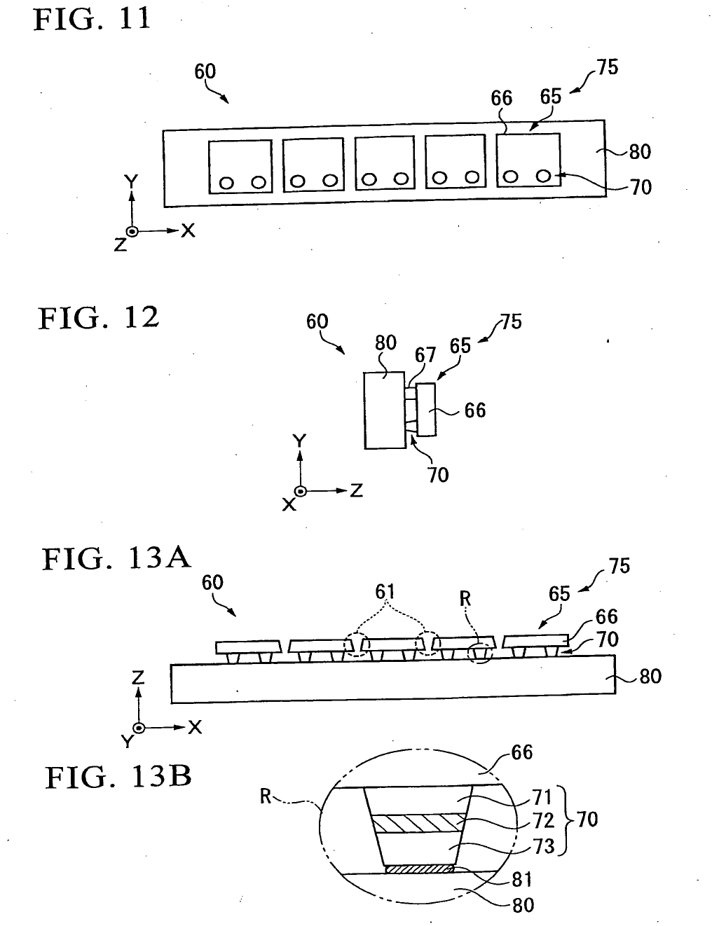

FIG. 11 shows a plane configuration of the laser light source seen from above (Z direction).

FIG. 12 shows a side configuration of the laser light source seen from a side (X direction).

FIGS. 13A and 13B show the laser light source. FIG. 13A shows a side configuration of the laser light source seen from a side (Y direction), and FIG. 13B is an enlarged cross-sectional view showing the area indicated by reference numeral R in FIG. 13A.

As shown in FIGS. 11 to 13B, the laser light source 60 includes a laser array chip 75 having five laser elements 65, and a submount 80. Also, as shown in FIG. 13A, division sections 61 are formed between the laser elements 65.

The laser elements 65 have a semiconductor substrate 66, a semiconductor multilayer film 70 serving as a emission section and formed on the semiconductor substrate 66, and a supporting protrusion 67 (shown in FIG. 12) to support the laser element 65.

The supporting protrusion 67 is formed from a semiconductor multilayer film similarly to the emission section.

The semiconductor multilayer films 70, two of which are formed in each of the laser elements 65 for a total of ten films, are arranged in an array in the X direction to form a one-dimensional laser array.

In this embodiment, a GaAs (gallium arsenide) is used as the material of the semiconductor substrate 66.

As shown in the enlarged view of FIG. 13B, in the semiconductor multilayer films 70, an n-DBR mirror 71, active layer 72 having a quantum-well structure, and p-DBR mirror 73 are layered to form a PIN diode.

Furthermore, in order to emit laser light having a high level of power, the semiconductor multilayer films 70 are etched to a circular mesa shape with the tip thinner on the side of the submount 80.

When a voltage is applied in the forward direction across electrodes (not shown) of these PIN diodes, electron-hole recombination occurs in the active layer 72, resulting in emission of light.

Hence induced emission occurs when the light generated travels between the n-DBR mirror 71 and the p-DBR mirror 73, and the light intensity is amplified.

The n-DBR mirror 71 and p-DBR mirror 72 are provided in order to impart a gain distribution to the light wavelength.

When the optical gain exceeds the optical loss, laser oscillation occurs and laser light is emitted from the semiconductor multilayer film 70 in the direction perpendicular to the face of the semiconductor substrate 66 (the Z direction, upward in FIGS. 13A and 13B).

In this embodiment, five laser elements 65 are fabricated, and two semiconductor multilayer films 70 are formed in each laser element 65, but the number of laser elements 65 and the number of semiconductor multilayer films 70 formed in each laser element 65, are not limited to these numbers.

Moreover, VCSEL devices are used as laser elements 65 and semiconductor multilayer films 70 are formed, but other configurations are possible, and for example a configuration may be adopted using an edge-emission type laser array in which the direction of optical resonance is parallel to the plane of the semiconductor substrate 66.

Furthermore, the laser elements 65 are not limited to semiconductor lasers, but may for example be solid state lasers, liquid lasers, gas lasers, free electron lasers, or other types of laser element.

The submount 80 is a member used for packaging each of the laser elements 65.

The submount 80 has, for example, a rectangular plate shape, measuring 10 mm to 12 mm in length, 1 mm to 5 mm in width, and of thickness 0.1 mm to 0.5 mm.

In this embodiment, Cu (copper), having satisfactory thermal conductivity, is used as the material of the submount 80.

The laser elements 65 and the submount 80 are connected via a solder layer 81. Specifically, between the laser elements 65 and the submount 80, the face of semiconductor multilayer films 70 which is close to the submount 80 is connected to the face of the submount 80 with the solder layer 81, shown in the enlarged view of FIG. 13B, intervening.

In this embodiment, AuSn (gold-tin), a conductive material, is used as the material of the solder layer 81.

Laser Light Source Manufacturing Method

Next, an example of a method of manufacture of the laser light source 60 is explained.

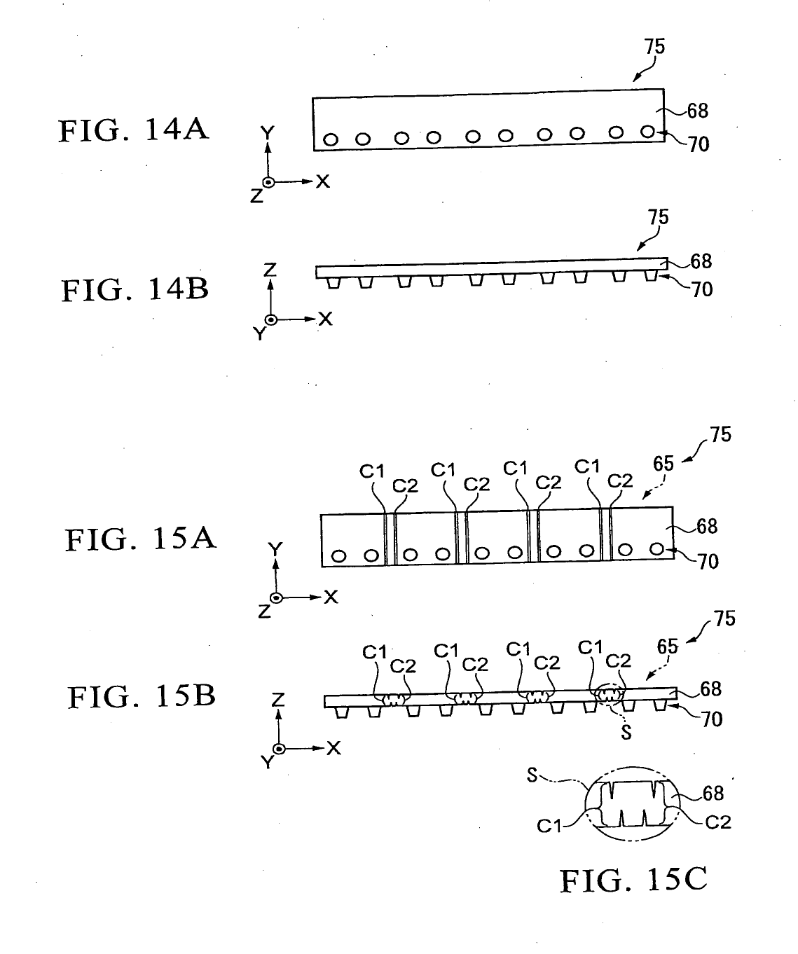

FIGS. 14A to 17C are schematic views illustrating a manufacturing processes for manufacturing a laser light source. FIGS. 14A, 15A, 16A, and 17A are plane views of the member which is to become the laser light source, seen from above (Z direction). FIGS. 14B, 15B, 16B, and 17B are side views seen from a side (Y direction). FIG. 15C is an enlarged cross-sectional view showing the area indicated by reference numeral S in FIG. 15B. FIG. 17C is an enlarged cross-sectional view showing the area indicated by reference numeral T in FIG. 17B.

First, as shown in FIGS. 14A and 14B, ten semiconductor multilayer films 70 are formed on a long semiconductor substrate 68 made of GaAs, to thereby form a laser array chip 75.

In this embodiment, the length in the X direction of the semiconductor substrate 68 is assumed to be 10 mm.

Furthermore, the semiconductor multilayer films 70 are formed by epitaxial growth.

For example, the MOCVD (Metal-Organic Chemical Vapor Deposition) method, MBE (Molecular Beam Epitaxy) method, or LPE (Liquid Phase Epitaxy) method may be used, modulating the composition while forming the semiconductor multilayer film 70.

The temperature when performing epitaxial growth is appropriately adjusted depending on the type of semiconductor substrate 68 or the types and thicknesses of layers constituting the semiconductor multilayer films 70. In general, a temperature of 600° C. to 800° C. is preferable.

The time duration when epitaxial growth is performed, similarly to the temperature determined as needed.

When forming the semiconductor multilayer films 70, each of the semiconductor multilayer films 70 thus formed is etched into a circular mesa shape so that the tip is narrower in the downward direction in the drawing, as indicated by the shape in the enlarged view of FIG. 13B.

Furthermore, a supporting protrusion 67 shown in FIG. 12 is also formed in proximity to each of the semiconductor multilayer films 70.

Next, division initiation sections, for division of the laser array chip 75 into five laser elements 65, are formed.

As shown in FIGS. 15A and 15B, two grooves are formed between adjacent laser elements 65 (between the first emission section, and the second emission section adjacent to the first emission section, of the invention), in the upper face (second fare) and lower face (first face) of the laser array chip 75 in the X direction, which is the direction of arrangement of the semiconductor multilayer films 70.

The two grooves (one in the upper face and one in the lower face), positioned on the left side in FIGS. 15A and 15B between laser elements 65, form a division initiation section C1. Also, the two grooves (one in the upper face and one in the lower face), positioned on the right side, form a division initiation section C2.

In this manner, eight grooves are formed as groove portions in both the upper face and in the lower face of the laser array chip 75.

Here, as shown in the enlarged view of FIG. 15C, the cross-section of each of the grooves has a V-shaped form.

These grooves are formed by, for example, using diamond or similar, the tip portion of which is formed in an acute-angle shape.

The intervals between division initiation sections C1 and C2 (in the X direction) between laser elements 65 are narrower in the lower face than in the upper face of the laser array chip 75.

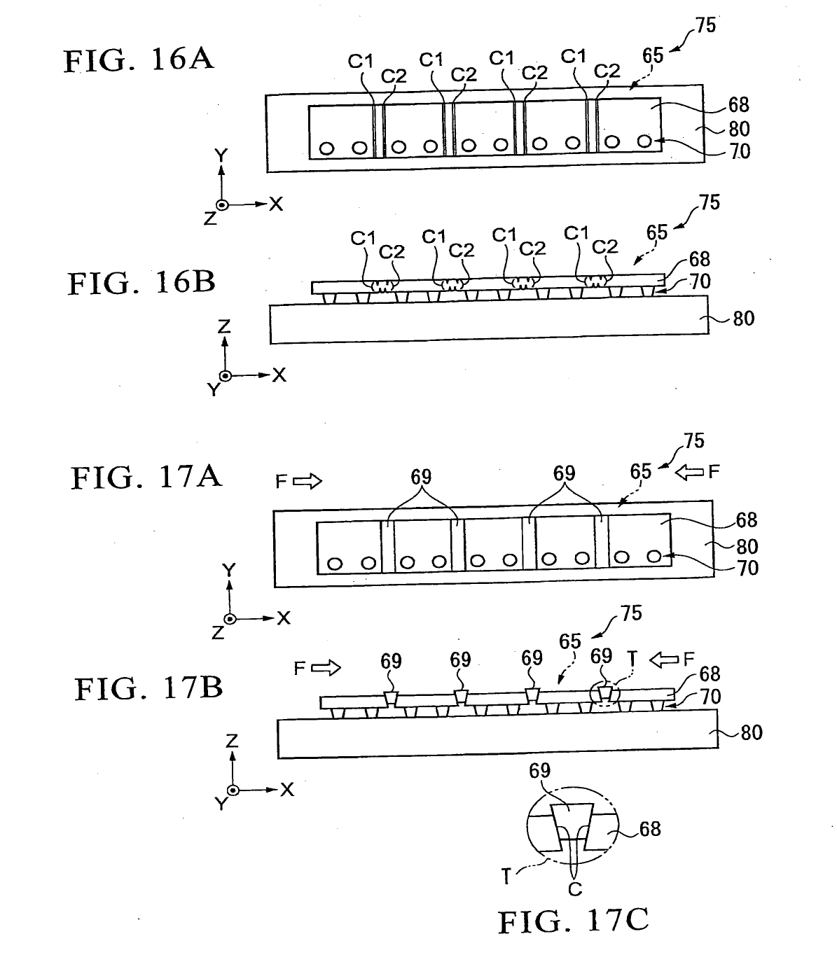

Next, as shown in FIGS. 16A and 16B, each of the semiconductor multilayer films 70 of the laser array chip 75 in which the division initiation sections C1 and C2 are formed are connected with the submount 80.

As shown in the enlarged view of FIG. 13B, in this connecting, the end faces of semiconductor multilayer films 70 which is close to the submount 80 are connected with the submount 80 by heating and melting AuSn which becomes the solder layer 81.

AuSn can be melted at 280 to 300° C.

This is a temperature which has no adverse effects on the semiconductor multilayer films 70.

Next, the temperature of the laser array chip 75 and the submount 80, in a bonded state with the semiconductor multilayer films 70 intervening, are returned to normal temperature in this state.

When the temperature of the two members are returned to normal temperature, due to the difference in linear expansion coefficients of the two members, the amounts of contraction of the two members are also different.

As a result, as shown in FIGS. 17A to 17C, a compressive stress F occurs acting in the X direction within the laser array chip 75.

By this compressive stress F, two cracks C occur between the laser elements 65 of the laser array chip 75, reaching from the upper face to the lower face, based on the division initiation sections C1 and C2 in the laser array chip 75 as shown in the enlarged view of FIG. 17C.

At this time, because the intervals between the division initiation sections C1 and C2 are narrower in the lower face than in the upper face of the laser array chip 75, the two cracks C occur so that the intervals become narrower depending on approaching tee lower face from the upper face.

By these cracks C between the laser elements 65, the laser array chip 75 is divided into five laser elements 65.

Between the laser elements 65, each of the substrate separation portions 69 which had been surrounded by two cracks C rises up somewhat due to the compressive stress F.

Each of the substrate separation portions 69, in this state of having risen up, is removed from above the semiconductor substrate 68, so that a laser light source 60 having two semiconductor multilayer films 70 formed in each laser element 65 can be obtained.

Effects

By the above-described embodiment, a laser light source 60 is formed from five laser elements 65 containing GaAs and a submount 80 containing Cu.

The linear expansion coefficients of GaAs and Cu are 5.9×10⁻⁶(1/K) and 16.59×10⁻⁶ (1/K), respectively.

Hence, for example, when a laser array chip 75 of length 10 mm in which division initiation sections have not been formed, is connected as-is to a submount 80, as shown in FIGS. 14A and 14B, and the temperature of both members are then returned to normal temperature, because the contraction amounts of the two members are different from each other, stress occurs in the laser array chip 75.

Furthermore, warping occurs in the laser array chip 75 and submount 80.

In contrast, in this embodiment division initiation sections C1 and C2 are formed between all of the laser elements 65 in the laser array chip 75.

In addition, the laser array chip 75 in which the division initiation sections C1 and C2 are formed is then connected to the submount 80 via each of the semiconductor multilayer films 70.

Thereafter, when the temperature of the laser array chip 75 and submount 80 are returned to normal temperature, due to the difference in the linear expansion coefficients of the two members, a compressive stress F acts on the laser array chip 75, and cracks C occur based on each of the division initiation sections C1 and C2.

By these cracks C, the laser array chip 75 is divided into five laser elements 65, and each of length is less than 2 mm. The division sections 61 caused by these cracks C are formed as shown in FIG. 13A.

Because cracks C occur due to compressive stress F arising from the difference in linear expansion coefficient of the two members, resulting in division into laser elements 65 of short length, the compressive stress F occurring in each of the laser elements 65 is released after the division and so suppressed.

Furthermore, warping of the laser elements 65 and submount 80 is also suppressed.

In this manner, the lifetime of the laser elements 65 can be extended with a high level of reliability.

Furthermore, after connecting the laser array chip 75 to the submount 80, upon returning to normal temperature, division occurs automatically. Hence there is no need for a process of cutting and machining the laser array chip 75, and tasks following the connecting of the laser array chip 75 to the submount 80 are simplified.

Furthermore, the intervals between the division initiation sections C1 and C2 between the laser elements 65 are narrower in the lower face than in the upper face of the laser array chip 75.

As a result, the two cracks C in each of the areas between the laser elements 65 diagonally occur.

In this manner, each of the substrate separation portions 69 surrounded by the two cracks C, receiving the compressive stress F, can easily be removed from the semiconductor substrate 68.

Furthermore, the two cracks C occur so that the interval therebetween becomes narrower in approaching the lower face from the upper face.

Therefore, each of the substrate separation portions 69, receiving the compressive stress F, rises up somewhat.

In this manner, the unnecessary substrate division portions 69 can easily be removed from above.

In this embodiment, the intervals between the division initiation sections C1 and C2 are narrower in the lower face of the laser array chip 75 than in the upper face.

However, this configuration is not limited to the invention, other configurations may be adopted, and for example, the intervals in the lower face of the laser array chip 75 may be made broader than the intervals in the upper face.

In this manner, two cracks C occur so that the interval therebetween becomes broader in approaching the lower face from the upper face.

Therefore, each of the substrate separation portions 69, receiving the compressive stress F, moves downward somewhat.

In this manner, the unnecessary substrate division portions 69 can easily be removed from below.

Furthermore, in this embodiment, grooves are formed in both the upper face and the lower face of the laser array chip 75 to serve as division initiation sections, but this configuration is not limited to the invention, other configurations may be adopted, and deep diagonal grooves capable of causing cracks may be formed in only one face, or other groove configurations may be employed to cause cracks.

Furthermore, the number of division initiation sections formed between laser elements 65 is not limited to the two portions C1 and C2, and further division initiation sections may be formed.

In general, when a laser array chip formed from GaAs and of length 10 mm is packaged on an AIN submount, there are few problems due to the difference in linear expansion coefficients of the two members.

In this embodiment, the GaAs is divided into laser elements 65 of length less than 2 mm, and Cu is used as the submount.

In this case, similarly to cases in which AIN is used as the submount, problems due to the difference in linear expansion coefficients can be avoided.

In the AIN, there are problems in that the high cost and low thermal conductivity. However, Cu is inexpensive and has high thermal conductivity compared with AIN. Thus, these problems can be alleviated.

Also, as shown in FIGS. 17A to 17C, the laser array chip 75 in which ten semiconductor multilayer films 70 are formed is divided into individual laser elements 65 while the laser array chip 75 is connected to the submount 80. Therefore, there are no problems in that scattering in the positional precision of the laser array formed by the semiconductor multilayer films 70 of the laser elements 65.

Furthermore, the semiconductor multilayer films 70 are etched into a circular mesa shape, the tip of which is narrower on the side of the submount 80.

In the invention, division may be performed so that each laser element 65 has one semiconductor multilayer film 70. But in this case, it is conceivable that because the semiconductor multilayer film 70 has a mesa shape, there may be erroneous inclination.

However, in this embodiment, division is performed so that each laser element 65 has two semiconductor multilayer films 70. Therefore, erroneous inclination of semiconductor multilayer films 70 can be prevented.

Furthermore, the portions of formation of division initiation sections can be reduced compared with the case of a single semiconductor multilayer film 70. Therefore, there is the advantage that laser light sources 60 can be rapidly manufactured.

As explained above, in this embodiment, the occurrence of stress within laser elements 65 in a laser light source 60, and the occurrence of warping of each of the laser elements 65 and of the submount 80, can be suppressed.

Furthermore, the semiconductor multilayer films 70 can be used to configure a laser array having a high level of positional precision, without scattering in positions or the occurrence of inclination.

Therefore, in this embodiment, shifts in laser light emitted from the laser light source 60 and degradation of positional precision can be prevented.

### Fourth Embodiment

Next, the manufacturing method of a fourth embodiment to which the invention is applied is explained.

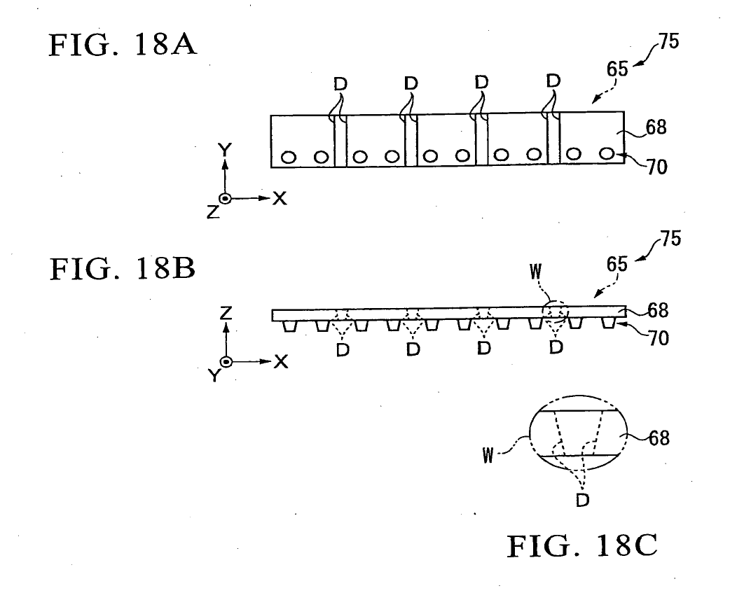

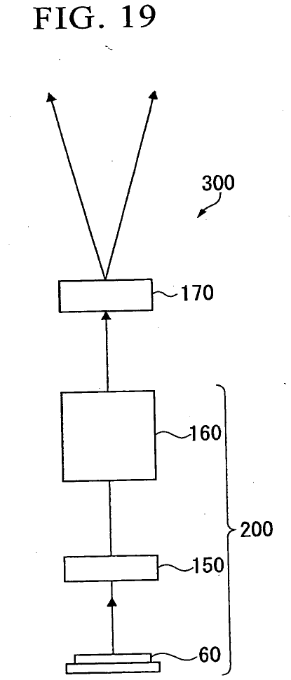

FIGS. 18A to 18C are schematic views illustrating a process in the manufacture of a laser light source. FIG. 18A is a plane view of a member which is to become the laser light source, seen from above (Z direction). FIG. 18B is a side view seen from one side (Y direction). FIG. 18C is an enlarged cross-sectional view showing the area indicated by reference numeral W in FIG. 18B.

The process shown in FIGS. 18A to 18C replaces the process shown in FIGS. 15A to 15C in the manufacturing method of the third embodiment, described above.

That is, in the manufacturing method of the fourth embodiment, in place of the grooves shown in FIGS. 15A to 15C, dicing lines D are formed as shown in FIGS. 18A to 18C, as division initiation sections of the laser array chip 75.

Other manufacturing processes are similar to those of the manufacturing method of the third embodiment, and detailed explanations are thereby omitted.

These dicing lines D are modified layers, in which the interior of the semiconductor substrate 68 is irradiated with laser light to modify the material so that cracks form easily.

An example of this dicing technique is the stealth dicing technique developed by Hamamatsu Photonics K.K.

Two dicing lines D (two division initiation sections), reaching from the upper face to the lower face of the semiconductor substrate 68, are formed between the laser elements 65 into which the laser array chip 75 is to be divided.

In this manner, a total of eight dicing lines is formed, as modification sections, in the semiconductor substrate 68.

Here, as shown in the enlarged view of FIG. 18B, the intervals between the two dicing lines D formed between laser elements 65 in the X direction become narrower in approaching the lower face from the upper face.

Next, each of the semiconductor multilayer films 70 on the laser array chip 75 on which the dicing lines D are formed are connected to the submount 80 (see FIGS. 16A and 16B).

Then, the laser array chip 75 and submount 80, in the connected state via the semiconductor multilayer films 70, are returned as-is to normal temperature.

At this time, a compressive stress F occurs in the X direction within the laser array chip 75 (see FIGS. 17A to 17C).

By this compressive stress F, cracks C occur, extending from the upper face to the lower face of the semiconductor substrate 68, along the two dicing lines D in each area between laser elements 65 of the laser array chip 75.

Here, each of the two cracks C occurs so that the interval therebetween becomes narrower in approaching the lower face from the upper face.

By these cracks C between the laser elements 65, the laser array chip 75 is divided into five laser elements 65.

In each area between laser elements 65, the substrate separation portion 69 surrounded by the two cracks C rises upward somewhat due to the compressive stress F.

Each of the substrate separation portions 69, in this state of having risen upward, can be removed from above the semiconductor substrate 68, so that a laser light source 60 is obtained in which two semiconductor multilayer films 70 are formed in each laser element 65.

By a manufacturing method in which dicing lines D are formed in the laser array chip 75 as division initiation sections, cracks can be reliably caused along the dicing lines D between the laser elements 65.

In this constitution, the laser array chip 75 can be reliably divided into five laser elements 65.

As the division initiation sections, in addition to the grooves shown in FIGS. 15A to 15C in the third embodiment, dicing lines D shown in FIGS. 18A to 18C in this embodiment may be formed.

In this constitution, cracks can be caused even more reliably in the laser array chip 75, and the laser array chip 75 can be divided even more reliably into five laser elements 65.

### Fifth Embodiment

### Illumination Device

First, an explanation is given of the configuration of the illumination device of a fifth embodiment to which the invention is applied.

FIG. 19 a schematic view showing the configuration of the illumination device of the fifth embodiment.

As shown in the FIG. 19, the illumination device 300 of this embodiment includes a laser light source device 200 and a diffusion device 170 which causes diffusion of the second harmonic (visible laser light) emitted from the laser light source device 200.

The laser light source device 200 includes the above-described laser light source 60, an external resonance mirror 150, and a wavelength conversion element 160.

The external resonance mirror 150 is a mirror which efficiently reflects light emitted from the laser light source 60 toward the laser light source 60.

A resonator structure to induce laser oscillation is formed by the external resonance mirror 150 and the p-DBR mirrors 73 of each of the laser elements 65.

Light emitted from the laser light source 60 is amplified during repeated reflections between the laser light source 60 and the external resonance mirror 150, and is emitted from the external resonance mirror 150.

The wavelength conversion element 160 is a nonlinear optical element which converts the wavelength of incidence light.

The wavelength conversion element 160 converts the wavelength of light emitted from the external resonance mirror 150 into substantial one-half wavelength, and outputs second harmonics which are for example blue, green, or the like.

The position of placement of the wavelength conversion element 160 is not limited to that of this embodiment, and the device may be placed between the laser light source 60 and the external resonance mirror 150. Also, an external resonance mirror need not be used.

By a laser light source device configured as described above, the p-DBR mirrors 73 of each of the laser elements 65 are arranged substantially in a single plane. Therefore, resonators with the p-DBR mirrors 73 of each of the laser elements 65 can be configured using a single external resonance mirror 150, and all of the laser elements 65 can efficiently oscillate the laser.

Furthermore, shifting of laser light emitted from the laser light source 60 and degradation of positional precision can be prevented.

As a result, the laser light source device can emit the laser light having high level of output power with a high level of reliability. The illumination device 300 can provide stable illumination with illumination light having a high level of performance and efficiency.

### Sixth Embodiment

### Monitor

In this embodiment, a monitor including the laser light source device 200 of the above-described fifth embodiment is explained.

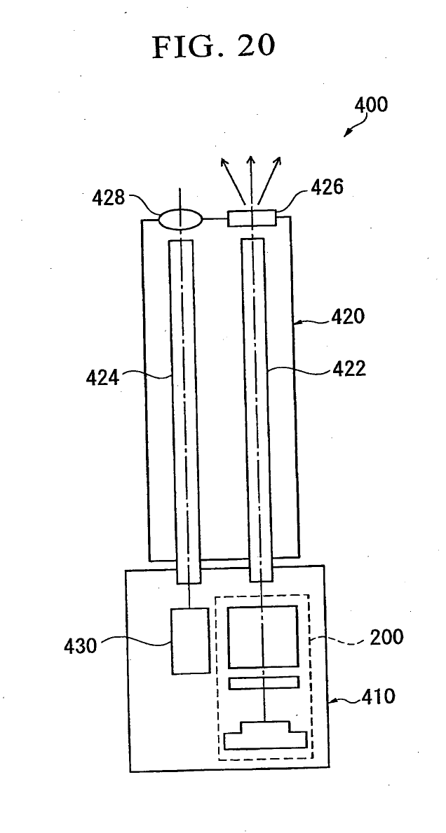

FIG. 20 is a schematic view showing the configuration of the monitor of the sixth embodiment to which the invention is applied.

As shown in the figure, the monitor 400 includes a device main unit 410 and a light transmission section 420.

The device main unit 410 includes the laser light source device 200 of the above-described fifth embodiment.

The light transmission section 420 includes two light guides 422 and 424, on the side transmitting light and on the side receiving light.

Each of the light guides 422 and 424 is formed by bundling together numerous optical fibers, and can transmit laser light to distant locations.

The laser light source device 200 is positioned on the incidence side of the light guide 422 transmitting light. A diffusion plate 426 is positioned on the emission side of the light guide 422.

The laser light emitted from the laser light source device 200 is transmitted along the light guide 422 to the diffusion plate 426 provided at the tip of the light transmission section 420, and is diffused by the diffusion plate 426 to irradiate the object.

An image-formation lens 428 is provided at the tip of the light transmission section 420, which can receive the light reflected from the object.

The reflected light is transmitted through the light guide 424 that receives the light, and is transmitted to a camera 430 serving as an image capturing section and provided within the device main unit 410.

As a result, the camera 430 can capture images based on reflected light, obtained by irradiating the object with laser light emitted from the laser light source device 200.

By the monitor 400 configured as described above, laser light having high level of output power with a high level of reliability can be emitted by the laser light source device 200. Therefore the brightness of images captured by the camera 430 can be increased with stability.

### Seventh Embodiment

### Image Display Device

In this embodiment, a projector is explained as an image display device including the laser light source device 200 of the above-described fifth embodiment.

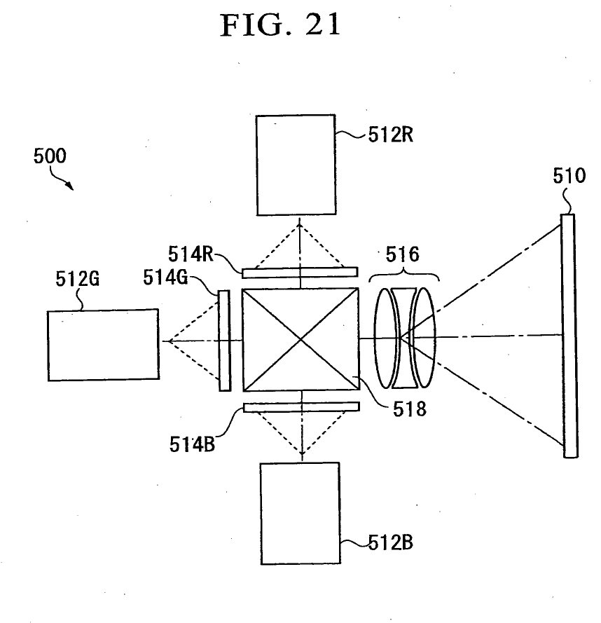

FIG. 21 is a schematic view showing the configuration of the image display device of the seventh embodiment to which the invention is applied.

For purposes of simplification, in FIG. 21, a housing of the projector 500 is not shown.

The projector 500 is a front-projection type projector which supplies light to the screen 510. A viewer observes images made by the light which is reflected by the screen 510.

Explanations which are the same explanations of the third embodiment described above are omitted.

As shown in FIG. 21, the projector 500 includes a red light illumination device 512R emitting red light, a green light illumination device 512G emitting green light, and a blue light illumination device 512B emitting blue light.

The red light illumination device 512R, the green light illumination device 512G, and the blue light illumination device 512B each have the same configuration as the illumination device 300 of the above-described fifth embodiment.

Each of the illumination devices for each color 512R, 512G, and 512B includes the laser light source device 200 and a diffusion device 170 which causes diffusion of the second harmonic emitted from the laser light source device 200.

In the wavelength conversion element 160 included in the red light illumination device 512R, wavelength conversion from infrared laser light to red light is performed, and in the wavelength conversion element 160 included in the green light illumination device 512G, wavelength conversion from infrared laser light to green light is performed. Also, in the wavelength conversion element 160 included in the blue light illumination device 512B, wavelength conversion from infrared laser light to blue light is performed.

Red, green, and blue laser light may also be directly emitted from laser light sources, without providing wavelength conversion elements.

The projector 500 includes liquid crystal light valves 514R, 514G, and 514B, which modulate the illumination light emitted from the illumination devices 512R, 512G, and 512B of the respective colors according to image signals sent from a computer or the like.

Furthermore, the projector 500 includes a cross-dichroic prism 518 which synthesizes the light emitted from the liquid crystal light valves 514R, 514G, and 514B and guides the light to a projection lens 516.

Also, the projector 500 includes a projection lens 516 which enlarges the image formed by the liquid crystal light valves 514R, 514G, and 514B and projects the image onto a screen 510.

The light of three colors modulated by the liquid crystal light valves 514R, 514G, and 514B is incident into the cross-dichroic prism 518.

This prism is formed by laminating four right-angle prisms. Dielectric multilayer films which reflect red light and dielectric multilayer films which reflect blue light are positioned in a cross shape on the inner faces of the prism.

Light of the three colors is synthesized by these dielectric multilayer films and light expressing a color image is formed.

Then, the synthesized light is incident into the image formation device, and the projection lens 516 which serves as the projection optical system projects the light onto a screen 510 serving as the display screen, and the image is enlarged to the desired size and displayed.

By the projector 500 configured as described above, each of the laser light source devices 200, which is included in the red light illumination device 512R, the green light illumination device 512G, and the blue light illumination device 512B, emits the laser light having high level of output power with a high level of reliability. Therefore, images having a high level of brightness can be stably displayed.

The projector 500 of this embodiment is a so-called three-chip liquid crystal projector. But in place of this, the projector may be a single-chip liquid crystal projector, in which the laser light source is lighted using time division for each color in a configuration enabling color display using only a single light valve.

Furthermore, the projector may be a projector having scanning section for scanning laser light from a laser light source device onto a screen. In this constitution, by this scanning section, an image is displayed on the display screen at a desired size.

Furthermore, the projector may be a so-called rear projector, in which light is supplied to a first surface of the screen, and light emitted from a second surface of the screen is observed by a viewer.

Furthermore, spatial light modulation devices are not limited to the transmissive liquid crystal display devices. As the spatial light modulation devices, reflective liquid crystal display devices (Liquid Crystal On Silicon, LCOS), DMDs (Digital Micrornirror Devices), GLVs (Grating Light Valves), or the like may be used.

As described above, various embodiments of the invention have been explained, but the invention is not limited to these embodiments, and various configurations can be adopted without deviating from the gist of the invention.

What is claimed is:

1. A laser array chip comprising:
a plurality of emission sections emitting laser lights; and
a weak section formed in a portion in the thickness direction of at least a portion of the areas between the emission sections, whose strength is weaker than the strength of areas in which the emission sections are formed.

2. The laser array chip according to claim 1, wherein
the weak section is a portion in which the thickness of the laser array chip is decreased due to a groove formed in the thickness direction of the laser array chip.

3. The laser array chip according to claim 1, further comprising:
a plurality of weak sections; wherein
the strengths of the weak sections are different from each other depending on the positions on which the weak sections are formed.

4. A laser module comprising:
a laser element having a plurality of emission sections emitting laser lights, and a rupture section caused by a weak section formed in a portion in the thickness direction of at least a portion of the areas between the emission sections, the strength of the weak section being weaker than the strength of areas in which the emission sections are formed; and
a supporting substrate having a linear expansion coefficient lower than the linear expansion coefficient of the laser element, and on which the laser element is packaged.

5. The laser module according to claim 4, wherein
the weak section is a portion in which the thickness of the laser element is decreased due to a groove formed in the thickness direction of the laser element.

6. The laser module according to claim 5, wherein
the laser element has a package face on which the supporting substrate is packaged, and the groove is formed on the package face.

7. The laser module according to claim 4, wherein
the laser element and the supporting substrate are connected via a connecting material including hard solder material.

8. A manufacturing method for manufacturing a laser module, the manufacturing method comprising.
providing a laser array chip having a plurality of emission sections emitting laser lights;
forming a weak section, in a portion of the thickness direction of the laser array chip, in at least a portion of the areas between the emission sections of the laser array chip;
connecting the laser array chip to a supporting substrate using a connecting material that has been heated; and
packaging the laser array chip on the supporting substrate.

9. The manufacturing method according to claim 8, wherein
the laser array chip has a package face on which the supporting substrate is packaged, the weak section is formed on the package face of the laser array chip, and the weak section is a portion in which the thickness of the laser array chip is reduced due to a groove formed in the thickness direction of the laser array chip.

10. A projector comprising:
a light source device having the laser module according to claim 4; and
an image formation device utilizing light emitted from the light source device and causing images having a desired size to be displayed on a display screen.

11. A laser array chip comprising:
a plurality of emission sections including a first emission section and a second emission section adjacent to the first emission section; and
at least two division initiation sections, in the area between the first emission section and the second emission section, along the direction of arrangement of the emission sections.

12. The laser array chip according to claim 11, further comprising:
a first face and a second face on the side opposite the first face, wherein
the division initiation sections are formed on each of the first face and the second face, and the intervals between the division initiation sections formed on the first face are narrower than the intervals between the division initiation sections formed on the second face.

13. The laser array chip according to claim 11, wherein
the division initiation sections are groove portions formed on the first face and the second face.

14. The laser array chip according to claim 11, wherein
the division initiation sections are modification sections formed in the laser array chip.

15. A manufacturing method for manufacturing a laser light source, the manufacturing method comprising:
providing a laser array chip having a plurality of emission sections including a first emission section and a second emission section adjacent to the first emission section;
forming, on the laser array chip, at least two division initiation sections at which the laser array chip is initially divided so as to divide the laser array chip into a plurality of laser elements, between the first emission section and the second emission section, along the direction of arrangement of the emission sections;
connecting the laser array chip in which the division initiation sections are formed, to a submount; and
dividing the laser array chip which has been connected to the submount into the laser elements.

16. The manufacturing method according to claim 15, wherein
in the dividing of the laser array chip, cracks are occurred at the division initiation sections at which the laser array chip is initially divided so as to divide the laser array chip into the laser elements, due to the stress caused by the difference in the linear expansion coefficients of the laser array chip and the submount.

17. The manufacturing method according to claim 15, wherein
the laser array chip has a first face facing to the submount when the laser array chip is connected to the submount and a second face which is opposite side of the first face, and wherein
in the forming of the division initiation sections, the division initiation sections are formed in the laser array chip so that the intervals between the division initiation sections in the first face are narrower than the intervals in the second face.

18. The manufacturing method according to claim 15, wherein
the division initiation sections are groove portions formed in the first face and the second face.

19. The manufacturing method according to claim 15, wherein
the division initiation sections are modification sections formed in the laser array chip.

20. The manufacturing method according to claim 15, wherein
the laser array chip is constituted by a material including a GaAs, and the submount is constituted by a material including a copper.

21. A laser light source manufactured by the manufacturing method according to claim 15.

22. An illumination device comprising
the laser light source according to claim 21.

23. A monitor comprising:
the laser light source according to claim 21; and
an image capturing section which captures images of objects irradiated by the laser light source.

24. A projector comprising:
the laser light source according to claim 21; and
an image formation device utilizing light from the laser light source and causing images having a desired size to be displayed on a display screen.
